(19) United States
(12) Patent Application Publication
(10) Pub. No.: US 2007/0224545 A1
(43) Pub. Date: Sep. 27, 2007

(54) METHOD FOR IMMERSION LITHOGRAPHY

(76) Inventor: Benjamin Szu-Min Lin, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,393

(22) Filed: Mar. 21, 2006

(51) Int. Cl. G03F 7/20

(52) U.S. Cl. 430/311; 430/327

(57) ABSTRACT

The invention is directed towards a method for immersion lithography by locally pre-treating the surface of the wafer. The surface of the wafer is treated locally with a pre-treatment process, so that the surface of the wafer is wettable to the later applied immersion liquid. The pre-treatment may includes applying a pre-treating liquid or performing a surface treatment to a predetermined region of the wafer surface or the photoresist layer to enhance the wettability of the surface of the wafer or the photoresist layer. The pre-treatment process is performed concurrently with the step of applying the immersion liquid for exposure.

### BACKGROUND OF THE INVENTION

1. Field of Invention

The present invention relates to a method for immersion lithography. More particularly, the present invention relates to a method for immersion lithography by pre-treating the surface of the wafer.

2. Description of Related Art

In the semiconductor fabrication process, as the dimension of devices on a chip becomes smaller, the resolution required for lithography needs to be higher. Therefore, an emerging technology that uses the refractive properties of fluids to improve the resolution of lithography, called immersion lithography, has been developed in semiconductor manufacturing. The lithographic system operating in the air has a numerical aperture between 0 and 1 due to the refractive index of 1 for the air. By operating your lithographic system in a liquid with a refractive index greater than 1, the numerical aperture of the lithographic system can be increased, because the numerical aperture is directly proportional to the refractive index of the medium light passing through.

In immersion lithography, a liquid is interposed between the projection lens and the surface of the wafer. Usually, for 193 nm immersion lithography, water appears to be the best medium for this purpose. Immersion technology offers better resolution over conventional projection lithography because the lens can be designed with numerical apertures greater than one, which create the ability to produce smaller features. Immersion lithography can provide a number of advantages, including effectively decreasing the wavelength of the exposure light and providing a considerable boost to the focus depth.

However, for the immersion lithography technology, certain technical problems still exist, such as bubbles in the immersion water or at the interface between the liquid and the surface of the wafer. Bubbles can be introduced during a variety of steps in the immersion lithography process. They can come from air trapped in wafer topography, for instance, or arise from the thermal effect created by the tool's laser pulse. Or they can occur during the injection or removal of the fluid from the space between lens and wafer.

Therefore, there is a need to develop an approach in immersion lithography technology to alleviate the bubble issues.

### SUMMARY OF THE INVENTION

It is therefore an object of the invention to provide a method for immersion lithography by locally pre-treating the surface of the wafer. The problems of micro-bubbles between the liquid and the surface of the wafer or the photoresist layer can be alleviated.

To achieve these objects and advantages, and in accordance with the purpose of the invention, as embodied and broadly described herein, the invention is directed towards a method for immersion lithography by pre-treating the surface of the wafer. Before applying the immersion liquid, the surface of the wafer is locally pre-treated with a predetermined amount of the pre-treating liquid, so that the surface of the wafer is wettable to the later applied immersion liquid. The pre-treating liquid may further include a wetting agent to enhance the wettability of the surface of the wafer or the photoresist layer. Alternatively, the wafer or the photoresist layer covering the wafer can be pre-treated locally with a surface treatment for enhancing wettability of the surface of the wafer or the photoresist layer.

Through the local pre-treatment, the surface of the wafer or the photoresist layer provides good wetting toward the immersion liquid, thus preventing the problems of bubbles between the liquid and surface of the wafer or the photoresist layer. In addition, the pattern fidelity of immersion lithography can be improved due to fewer defects.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A-1C are schematic cross-sectional views of the process steps for immersion lithography according to one preferred embodiment of this invention. FIG. 1A′ is a schematic cross-sectional view of the pre-treatment process according to another preferred embodiment of this invention. FIG. 1D is a schematic top view of the pre-treatment zone and the exposure region shown in FIG. 1A.

### DESCRIPTION OF THE PREFERRED EMBODIMENTS

For the immersion lithographic system, usually a thin layer of an immersion liquid (or water) is injected between the projection lens and the surface of the wafer or the photoresist layer over the wafer, before exposure. The liquid covers a predetermined region (i.e. the exposure region, below the lens) of the wafer, rather than the entire wafer. After exposure, the injected water is removed and the wafer is moved by the wafer stage to reposition at the next exposure region. The aforementioned process is repeated until the whole wafer is exposed.

In order to lessen or prevent the formation of micro-bubbles, the present invention provides a method for immersion lithography by pre-treating the surface of the wafer or the photoresist layer.

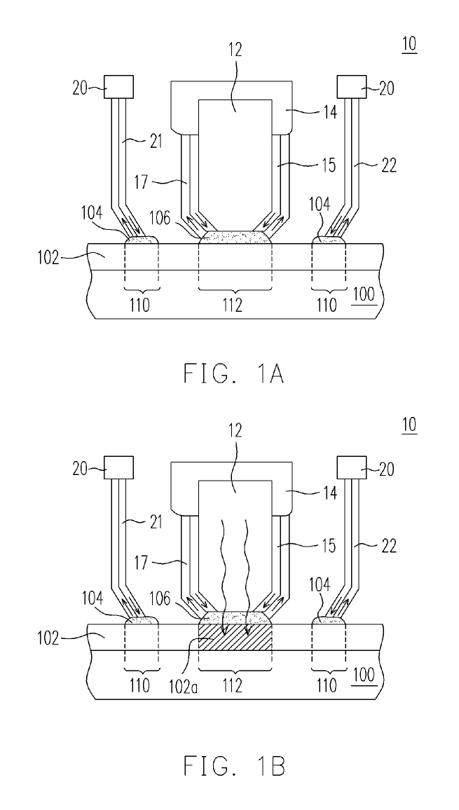

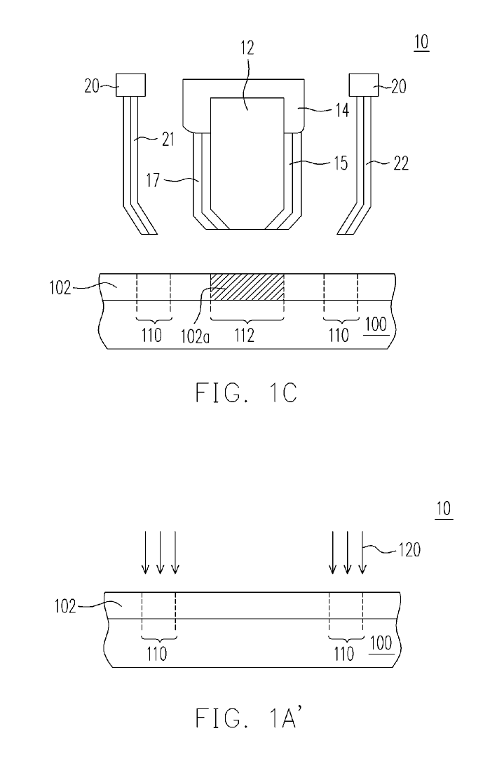

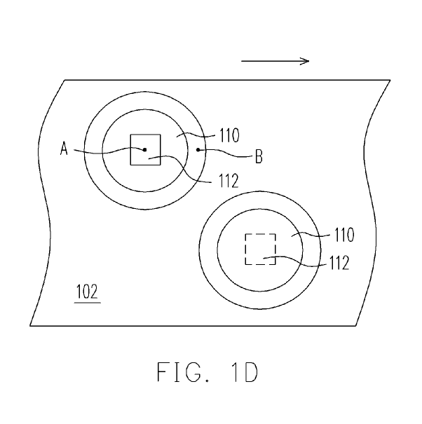

FIGS. 1A-1C are schematic cross-sectional views of the process steps for immersion lithography according to one preferred embodiment of this invention. FIG. 1D is a schematic top view of the pre-treatment zone and the exposure region shown in FIG. 1A.

As shown in FIG. 1A, a semiconductor wafer 100 is provided to the immersion lithographic system 10. The wafer 100 may include a plurality of material layers (not shown) and a photoresist layer 102 thereon. According to the preferred embodiment of this invention, a pre-treatment process is performed concurrently with the step of applying the immersion liquid. During the pre-treatment process, from a liquid supply 20 of the immersion lithographic system 10, a small amount of a pre-treating liquid 104 is sprayed onto the wafer surface (the surface of the photoresist layer 102). The pre-treating liquid 104 spreads over the surface of the photoresist layer 102, but the distribution of the pre-treating liquid 104 is limited to be within a pre-treatment zone 110, as shown in FIGS. 1A and 1D. The pre-treatment zone 110, for example, is a ring-shaped region. The amount of the pre-treating liquid 104 can be precisely controlled so that the pre-treating liquid 104 will not interfere with the following exposure step or overflow from the pre-treatment zone 110. For example, through the design of the injection tube 21 and the suction tube 22, the distribution of the pre-treating liquid 104 can be properly controlled. For example, by adjusting the distance between the tubes 21/22 and by controlling the injection rate relative to the suction rate, the coverage region of the pre-treating liquid 104 can be controlled. The pre-treating liquid 104 can be water, water with a wetting agent, any suitable solvent without or with a wetting agent, for example. The wetting agent may be a surfactant, for example. The pre-treating liquid 104 can change the hydrophobic surface of the photoresist layer 102 into a hydrophilic surface.

Referring to FIG. 1A, at the same time as performing the pre-treatment process, a thin layer of an immersion liquid 106 is injected between the projection lens 12 and the photoresist layer 102 over the wafer 100 in the immersion lithographic system 10 for the exposure step. The immersion liquid 106 covers an exposure region 112 (i.e. the, predetermined region below the lens) of the photoresist layer 102 over the wafer 100, as shown in FIGS. 1B and 1D. The liquid 106 can be injected through an inlet 15 of the lens housing 14 and sucked up through an outlet 17 of the lens housing 14 by vacuum, for example. For example, by adjusting the positions of the inlet/outlet 15/17 and by controlling the injection rate relative to the suction rate, the size or the shape of the coverage region of the liquid 106 can be well controlled. Preferably, the liquid 106 is de-ionized and/or degassed water. However, the applied liquid 106 can be any liquids with suitable absorption coefficient, refractive index or photo-reactivity.

From FIG. 1D, the exposure zone 112 is surrounded by the pre-treatment region 110. Preferably, the exposure zone is located at a central portion of the pre-treatment region 110. The shape of the pre-treatment region 110 is not limited to be ring-like or arc, but the shape or the size of the pre-treatment region 110 can be adjusted according to the process requirements or the design of the lithographic system. Similarly, although the shape of the exposure zone 112 is tetragonal in FIG. 1C, the exposure zone 112 can be round or in other suitable shapes, and the shape or the size of the exposure zone 112 can be varied and depend on the design of the mask or the lithographic system.

Subsequently, as shown in FIGS. 1B and 1D, aligning the lens 12 to the location (A), the exposure step is performed with the liquid 106 interposed between the lens 12 and the photoresist layer 102. The exposure step is well known to persons skilled in the art, and will not be further described in details therein.

As shown in FIG. 1C, after exposure, the injected water between the lens 12 and the photoresist layer 102 is removed. The pre-treating liquid 104 used in the pre-treatment can be removed before or during exposure, or removed along with the immersion liquid 106.

Afterwards, the wafer 100 is moved (the moving direction is shown as the arrow in FIG. 1D) by the wafer stage to the next location (B) (reposition at the next exposure zone) for pre-treatment, injection of the immersion liquid and exposure. The aforementioned processes are repeated until the whole wafer is exposed.

According to this invention, the pre-treatment is performed concurrently with the step of applying the immersion liquid. However, for the location (B), the location (B) has been pre-treated before the next application of the immersion liquid for exposure.

The major purpose of the pre-treatment is to enhance wettability of a predetermined local region of the wafer surface (the surface of the photoresist layer). FIG. 1A′ is a schematic cross-sectional view of the pre-treatment process according to another preferred embodiment of this invention. In this embodiment, instead of using pre-treating liquid, the pre-treatment process may include locally treating the wafer surface (the surface of the photoresist layer 102) with a surface treatment 120. That is, the pre-treatment zone 110 of the photoresist layer 102, as shown in FIG. 1C, is treated with an oxygen-containing plasma or an oxidizing agent, for example, to modify the surface properties of the photoresist layer 102. The surface treatment 120 can change the hydrophobic surface of the photoresist layer 102 into a hydrophilic surface, within the range of the pre-treatment zone 110.

By performing the pre-treatment process to a local region (the pre-treatment region) of the wafer (or the photoresist layer), the surface properties of the pre-treatment region can be modified. So that the surface of the photoresist layer of the pre-treatment region becomes more wettable to the later applied liquid. Since the pre-treatment region encompasses the exposure zone, the wafer surface (the surface of the photoresist layer) in the exposure zone has been treated and becomes more wettable before applying the immersion liquid. By doing so, less or no micro-bubbles are formed during the injection of the immersion liquid or the exposure step, and the pattern fidelity can be improved due to less defects.

Furthermore, since the pre-treatment process is an in-situ process and the wafer needs not to be transferred to another system or platform for pre-treatment, delays or contaminations between different processing systems can be prevented. Because the pre-treatment process is performed right before the injection of the immersion liquid and exposure, the wetting effects of the pre-treatment process are satisfactory.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for immersion lithography, comprising:
providing a wafer having at least a photoresist layer to an immersion lithographic system;
performing a pre-treatment process to a first region of a surface of the photoresist layer over the wafer, and concurrently providing a liquid covering a second region of the surface of the photoresist layer and between the photoresist layer and a lens element of the immersion lithographic system, wherein the first region surrounds the second region, and wherein the surface of the photoresist layer is in contact with the liquid and the surface of the photoresist layer in the first region is wettable to the liquid; and
performing an exposure step to the second region of the surface of the photoresist layer with the liquid between the photoresist layer and the lens element of the immersion lithographic system.

2. The method as claimed in claim 1, wherein the step of performing the pre-treatment process includes providing a pre-treating liquid to the first region of the surface of the photoresist layer over the wafer.

3. The method as claimed in claim 2, wherein the pre-treating liquid is de-ionized water.

4. The method as claimed in claim 3, wherein the pre-treating liquid further includes a wetting agent.

5. The method as claimed in claim 2, wherein the pre-treating liquid includes a wetting agent.

6. The method as claimed in claim 1, wherein the step of performing the pre-treatment process includes performing a surface treatment to the first region of the surface of the photoresist layer over the wafer.

7. The method as claimed in claim 6, wherein the surface treatment includes treating the surface of the photoresist layer using an oxygen-containing plasma for increasing wettability of the surface of the photoresist layer.

8. The method as claimed in claim 6, wherein the surface treatment includes treating the surface of the photoresist layer with an oxidizing agent.

9. The method as claimed in claim 1, wherein second region is located in a central portion of the first region.

10. The method as claimed in claim 1, wherein the pre-treatment process is performed in-situ in the immersion lithographic system.
